(19) United States
(12) Patent Application Publication
(10) Pub. No.: US 2015/0004365 A1
(43) Pub. Date: Jan. 1, 2015

(54) INSULATING AND THERMALLY CONDUCTIVE SHEET

(71) Applicant: Toyobo Co., Ltd., Osaka (JP)

(72) Inventors: Hirokazu Nishimura, Shiga (JP); Kana Hashimoto, Shiga (JP)

(73) Assignee: Toyobo Co., Ltd., Osaka (JP)

(21) Appl. No.: 14/367,978

(22) PCT Filed: Dec. 28, 2012
(86) PCT No.: PCT/JP2012/084055

§ 371 Date: Jun. 23, 2014

(30) Foreign Application Priority Data
Dec. 28, 2011 (JP) 2011-287573

(51) Int. Cl. H05K 7/20; B05D 5/00

(52) U.S. Cl. CPC H05K 7/20481; B05D 5/00
USPC 428/141; 427/462

(57) ABSTRACT

To provide a high heat dissipation sheet that enables electrical insulation properties while also making possible a simple construction method.

In the present invention, short fibers with electrical insulation properties and thermal conductive properties are electrostatically flocked at high density onto a substrate coated with adhesive, under conditions that allow for high density electrostatic flocking, the erect short fibers are adhered and fixed, binder resin is impregnated and is hardened, and subsequently one surface of the sheet is abraded so that the insulating and thermally conductive fibers penetrate and are arrayed at high density in the direction of the sheet thickness. As a result, a heat dissipation sheet is formed in which the fibers protrude from one surface while the opposite surface is made smooth so that heat from an exothermic material can be quickly absorbed by the opposite surface and quickly dissipated into the air by the fiber protrusion surface.

### TECHNICAL FIELD OF THE INVENTION

The present invention relates to an insulating and thermally conductive sheet which is electrically insulating and has high heat dissipating property. More particularly, it relates to an insulating and thermally conductive sheet which can efficiently diffuse the heat from exothermic materials such as electronic substrate, semiconductor chip and light source while ensuring the insulation reliability.

### BACKGROUND ART

As a result of making an electronic instrument thinner and shorter and also more highly outputting, importance of heat dissipating measures therefor has been increasing. As a method for dissipating the heat from an exothermic material such as semiconductor or LED, it has been common to attach a heat dissipating material made of metal such as aluminum or copper thereto. Generally however, metal is electrically conductive. Therefore, when insulating property is needed, an insulating material is inserted between an exothermic material and a heat dissipating material so as to retain the insulating property. A big problem therein is that, generally, an insulating material has low electric conductivity and lowers the heat dissipating characteristic. In addition, since an exothermic material, an insulating material and a heat dissipating material should be bonded with each other, number of steps increases and that is disadvantageous in view of the cost.

As a member for conducting the heat from an exothermic material such as semiconductor or LED to a heat dissipating material, there has been proposed a member wherein an insulating and thermally conductive filler such as fine particles of metal oxide is filled in a binder.

However, in such a member, thermal conductance is inhibited due to the existence of a binder resin having relatively low thermal conductance and of gaps among the fillers whereby no sufficient thermal conductivity is achieved. In addition, when the filler is filled in high density for achieving the thermal conductivity, strength of the sheet lowers and, moreover, flexibility of the sheet is deteriorated whereby close adhesion to a thing to be adhered is reduced and, as a result, no high thermal conductivity is achieved in an actually implemented state.

On the other hand, for solving the insufficient thermal conductivity as such, there has been proposed an art wherein an insulating and thermally conductive fiber is arranged in the thermally conductive direction so that the thermal conductivity is efficiently carried out (for example, see Patent Documents 1-3). In Patent Documents 1 and 2, there is proposed a method for manufacturing an insulating and thermally conductive sheet wherein insulating and thermally conductive fiber is orientated in an erect state in the thickness direction of the sheet by electrostatically flocking the insulating and thermally conductive fiber on a layer to fix the flocked layer and then impregnating a binder resin thereinto. In Patent Document 3, there is proposed a method for manufacturing an insulating and thermally conductive sheet wherein magnetic field is applied onto a binder resin to which an insulating and thermally conductive fiber is added so as to orientate the fiber in the binder resin followed by fixing it. However, in the art concerning Patent Documents 1 to 3, although improvement is done in such a respect that thermal conductivity is efficiently achieved using a small amount of filler, there is a problem that it is not possible to fill the filler in high density and that no sufficient thermal conductivity is achieved.

On the other hand, Non-Patent Document 1 records the actual result that a nylon fiber having 1.5 d fineness and 0.5 mm fiber length is used to result in an electrostatic flocking of 94,700 fibers/cm² or, in other words, 14% density. Further, Patent Document 4 mentions that it is general in the usual electrostatic flocking art that the flocking basis weight is about 100 to 150 g/m² regardless of thickness and length of the flocked short fiber. This means that, when short fiber of 1.2 g/cm³ density and 0.4 mm fiber length is used for example, volume of the short fiber to the whole sheet volume corresponds to 30%. As such, Patent Document 0.4 mentions that a high-density electrostatic flocking is possible. However, the conventional electrostatic flocking mentioned in Non-Patent Document 1 is generally utilized as a manufacturing art for a napped material used for clothing, carpet, heat-insulating material, etc. whereby an extremely erect property of the fiber is not demanded and many fibers being greatly inclined are also contained therein. Therefore, when an insulating and electrically conductive sheet is manufactured utilizing the conventional electrostatic flocking art, the inclined fibers cannot penetrate into the thickness direction of the sheet whereby no high penetrating density is achieved.

### PRIOR ART DOCUMENTS

### Patent Documents

Patent Document 1: Japanese Patent No. 45219374
Patent Document 2: Japanese Patent No. 4443746
Patent Document 3: Japanese Patent No. 4272767
Patent Document 4: Japanese Patent Application
Laid-Open (JP-A) No. 299890/96

### Non-Patent Documents

Non-Patent Document 1: “Practice of flocking process” (Shin-koubunshi bunko), Norimasa Iinuma

### DISCLOSURE OF THE INVENTION

### Problem that the Invention is to Solve

The present invention has been achieved on the basis of the problems in the prior art as such. Thus, an object of the present invention is to provide a thermally conductive sheet having excellent insulating property and thermal conductivity.

### Means for Solving the Problem

As a result of intensive investigations, the present inventors have found that the above problems can be solved according to the following means and achieved the present invention.

Thus, the present invention comprises the following constitutions:

(1) An insulating and thermally conductive sheet, characterized in that, the sheet contains an insulating and thermally conductive fiber which penetrates the sheet in its thickness direction and a binder resin, that the surface roughness on at least one side of the sheet is 15 μm or less, and that the penetrating density of the insulating and thermally conductive fiber is 6% or more.

(2) The insulating and thermally conductive sheet according to (1), wherein an average value of inclination of the insulating and thermally conductive fiber to the sheet surface is 60 to 90°.

(3) The insulating and thermally conductive sheet according to (1) or (2), wherein an average value of the ratio of thermal conductivity of the insulating and thermally conductive sheet in the thickness direction to that in the surface direction is 2 to 12.

(4) The insulating and thermally conductive sheet according to any of (1) to (3), wherein the insulating and thermally conductive fiber is protruded in the length of 50 to 1,000 μm on a surface (surface B) opposite to the smooth surface (surface A) having the surface roughness of 15 μm or less.

(5) The insulating and thermally conductive sheet according to any of (1) to (4), wherein the durometer hardness is 80 or less in terms of Shore A hardness and 5 or more in terms of Shore E hardness.

(6) The insulating and thermally conductive sheet according to any of (1) to (5), wherein the volume intrinsic resistance is 10¹² Ω·cm or more.

(7) The insulating and thermally conductive sheet according to any of (1) to (6), wherein the evaluation in a UL 94 flame resistance test is V-0.

(8) The insulating and thermally conductive sheet according to any of (1) to (7), wherein the insulating and thermally conductive fiber is any of boron nitride fiber, high-strength polyethylene fiber and polybenzazole fiber.

(9) The insulating and thermally conductive sheet according to any of (1) to (8), wherein the binder resin is any of silicone resin, acrylic resin, urethane resin, EPDM resin and polycarbonate resin.

(10) The insulating and thermally conductive sheet according to any of (1) to (9), wherein the penetrating density of the insulating and thermally conductive fiber is 6 to 50%.

(11) A method for manufacturing an insulating and thermally conductive sheet, characterized in that, the method comprises:

a step of erecting an insulating and thermally conductive short fiber by means of electrostatic flocking, onto a substrate to which an adhesive is applied;

a step of adhering and fixing the erected insulating and thermally conductive short fiber by heating and, optionally shrinking the substrate together with the adhesion/fixing or after the adhesion/fixing;

a step of impregnating a binder resin into the insulating and thermally conductive short fiber which is erected on the substrate, and hardening the binder resin; and

a step of abrading both surfaces under the state of being detached from the substrate or of being fixed to the substrate.

### Advantages of the Invention

In accordance with the insulating and thermally conductive sheet of the present invention, it is now possible to quickly escape heat from an exothermic material such as semiconductor or LED while ensuring the insulation reliability whereby thermal damage of electronic instruments and light sources can be reduced.

### BRIEF DESCRIPTION OF THE DRAWINGS

FIG. 1 is an example of a method for manufacturing an insulating and thermally conductive sheet in the present invention.

FIG. 2 is a graph showing a preferred manufacturing condition in the present invention.

FIG. 3 is an example of calibration curves for E and penetrating density in the present invention.

### BEST MODE FOR CARRYING OUT THE INVENTION

Hereinafter, the present invention will be illustrated in detail.

It is essential that the insulating and thermally conductive sheet of the present invention contains an insulating and thermally conductive fiber which penetrates the sheet in its thickness direction and a binder resin. The insulating and thermally conductive fiber which penetrates the sheet in its thickness direction moves the heat generated from the exothermic material to the opposite side of the sheet and transfers the heat to the air or to a cooling material.

It is also necessary that, in the insulating and thermally conductive sheet of the present invention, at least one side of the sheet is smooth. Due to the smoothness, the insulating and thermally conductive fiber tightly adheres onto the exothermic surface whereby the heat can be efficiently conducted. Further, in case a cooling material is installed on the opposite side of the smooth side, the opposite side should be also smooth so that the opposite side is tightly adhered to the cooling material whereby the heat is efficiently conducted. When the cooling material is not installed on the opposite side and heat is dissipated to the air, it is necessary that, in the opposite side, an insulating and thermally conductive fiber which penetrates the sheet in its thickness direction is protruded. As a result of protrusion of the insulating and thermally conductive fiber, surface area becomes big and heat dissipating characteristic is enhanced.

Durometer hardness of the insulating and thermally conductive sheet of the present invention is preferred to be 80 or less in terms of Shore A hardness and 5 or more in terms of Shore E hardness, and more preferred to be 70 or less in terms of Shore A hardness and 10 or more in terms of Shore E hardness. When the Shore A hardness is low, a sheet can tightly adhere along the slightly uneven surfaces of the exothermic material and the heat dissipating material whereby an efficient thermal conductance is possible. On the other hand, when the Shore E hardness is high, a handling property when the sheet is installed into an electronic instrument or light source becomes good.

The volume intrinsic resistance of the insulating and thermally conductive sheet of the present invention is preferred to be 10¹⁰ Ω·cm or more, more preferred to be 10¹² Ω·cm or more, and further preferred to be 10¹³ Ω·cm or more. When the volume intrinsic resistance is high, it can be advantageously used also for such an application requiring high insulation reliability such as peripheral device of electric source. Although there is no particular limitation for the upper limit of the volume intrinsic resistance, it is about 10¹⁶ Ω·cm.

Flame resistance of the insulating and thermally conductive sheet of the present invention is preferred to be V-0. When it is V-0, the spread of fire can be reduced when inflammation happens due to short circuit or deterioration of the circuit in the electronic instruments.

Thermal conductivity and insulating property in the thickness direction of the insulating and thermally conductive sheet of the present invention can be achieved by a selection of the insulating and thermally conductive fiber which penetrates the sheet in its thickness direction and the insulating binder resin which supports it, and also by a manufacturing method which will be mentioned later.

Thickness of the sheet is preferred to be 10 to 300 μm and more preferred to be 50 to 80 μm. When it is thinner than 10 μm, strength of the sheet lowers and handling property is deteriorated. On the other hand, when it is more than 300 μm, heat resistance becomes big.

With regard to the insulating and thermally conductive fiber, it is not particularly specified so far as it is a fiber having electric insulation property and high thermal conductivity. For example, boron nitride fiber, high-strength polyethylene fiber, polybenzazole fiber, etc. are listed. Among them, polybenzazole fiber is particularly preferred because it also has heat resistance and is easily available. Although carbon fiber exhibits high thermal conductivity, it is electrically conductive whereby it is not suitable for the use in the present invention which requires electric insulation property.

As to the polybenzazole fiber, it is possible to purchase its commercially available product (Zylon manufactured by Toyobo).

Thermal conductivity of the insulating and thermally conductive fiber is preferred to be 20 W/mK or more, and more preferred to be 30 W/mK or more. When the thermal conductivity is 20 W/mK or more, a high thermal conductivity can be achieved when the fiber is made into a sheet.

Volume intrinsic resistance of the insulating and thermally conductive fiber is preferred to be 10¹⁰ Ω·cm or more, more preferred to be 10¹² Ω·cm or more, and further preferred to be 10¹³ Ω·cm or more. Since the volume intrinsic resistance of the insulating and thermally conductive fiber is nearly identical with the volume intrinsic resistance of the sheet, a high volume intrinsic resistance is needed.

Although the insulating and thermally conductive fiber may have any cross-sectional shape, a circular shape is preferred since it facilitates increase of the penetrating density. Although there is no particular limitation for its diameter, 1 mm or less is preferred in view of uniformity of heat dissipating object.

A binder resin is preferred to be excellent in heat resistance, electric insulation property and heat stability. When a binder resin is appropriately selected, those physical properties can be adjusted to the desired range. It is preferred to select a resin having excellent flexibility or a resin having an adhesive property by taking the tight adhesion to an exothermic material into consideration. Examples of the material having excellent flexibility include silicone resin, acrylic resin, urethane resin, EPDM and polycarbonate resin. Examples of the material having an adhesive property include thermosetting resin in a semi-set state. As to a material having excellent flexibility, silicone resin is particularly preferred because it has little changes in physical properties in a heat cycle and it hardly deteriorates. As to a material having an adhesive property, urethane resin is preferred because it has a good shock absorbing property against heat shock at the adhered interface to an exothermic material. It is also possible to impart flame resistance to a thermally conductive sheet by selecting a flame resisting material.

The penetrating density of the fiber is necessary to be 6% or more and is preferred to be 6 to 50%, and more preferred to be 10 to 40%. When it is less than 6%, the thermal conductivity in the thickness direction of the sheet lowers. When it is more than 50%, strength of the sheet lower and a handling property is deteriorated.

Density of the flocked fiber in the present invention can be evaluated by a method which will be mentioned later in Examples.

Length of the fiber may be adjusted depending upon the thickness of the sheet and it is essential that the fiber penetrates the sheet in its thickness direction. When the opposite side to the smooth surface is an air layer, the protruded length of the insulating and thermally conductive fiber which protrudes to the opposite side is preferred to be 10 to 1,000 μm. As a result of the fact that it is 10 μm or more, surface area of the fiber increases and heat can be efficiently transferred to the air. When it is more than 1,000 μm, heat does not reach to the front end of the fiber and, since the heat dissipating characteristic is not improved any more, that is not advantageous in terms of cost. Further, the protruded fiber is preferred to be coated with a resin or the like containing heat radiating agent such as carbon black for improving the heat dissipating characteristic.

Protruded amount of the fiber on the smooth surface of the sheet and variation thereof can be evaluated by means of a surface roughness of the sheet. The average surface roughness is preferred to be 4 μm or less. In case the average surface roughness is more than 4 μm, the fiber lies down when it adheres to the exothermic material and the heat dissipating material whereby the heat dissipating amount lowers. In addition, since the tight adhesion to exothermic material and to heat dissipating material is deteriorated, a heat dissipating property lowers.

The sheet of the present invention may be in such a state that the surface thereof is applied with an adhesive. There is no particular limitation for the adhesive and examples thereof include acrylate resin, epoxy resin, silicone resin and a resin composition wherein a highly thermally conductive filler such as metal, ceramic or graphite is mixed with the above-exemplified resin.

The insulating and thermally conductive sheet according to the present invention can be manufactured by a method comprising the following steps.
(i) a step of erecting an insulating and thermally conductive short fiber by means of electrostatic flocking, onto a substrate to which an adhesive is applied;
(ii) a step of adhering and fixing the erected insulating and thermally conductive short fiber by heating and, optionally shrinking the substrate together with the adhesion/fixing or after the adhesion/fixing;
(iii) a step of impregnating a binder resin into the insulating and thermally conductive short fiber which is erected on the substrate, and hardening the binder resin; and
(iv) a step of abrading both surfaces under the state of being detached from the substrate or of being fixed to the substrate.

Electrostatic flocking is such a method wherein a substrate is arranged on one of the two electrodes while a short fiber is arranged on another and then high voltage is applied thereto whereby the short fiber is charged and anchored on the substrate side followed by fixing using an adhesive.

Although the material of the adhesive used in the above step is not particularly limited so far as it can be removed in the abrading step thereafter, the material having less insulating property is preferred because the electrostatic flocking in higher density can be conducted thereby. For example, an aqueous dispersion of acrylic resin is advantageously used as an adhesive. Alternately, a binder resin itself may be used as an adhesive. For achieving the high flocking density in the electrostatic flocking, it is preferred to enhance the electrostatic attractive force. For such a purpose, it is preferred that the thickness of the applied adhesive is small. However, the thickness of the adhesive needs to be big to such an extent that it can fix the anchored fiber. Accordingly, the thickness is preferred to be 10 to 50 μm and more preferred to be 10 to 30 μm.

In order to achieve a high flocking density in the electrostatic flocking, it is preferred to enhance the electrostatic attractive force. Therefore, as to a substrate of the present invention, a material having low electric insulation property is preferred. In addition, for a purpose of reducing the cost, it is preferred to select such a material that can be detached from the sheet after fixing a binder. For example, metal foil, polyethylene terephthalate film coated with an electroconductive agent, graphite sheet, etc. may be used as a substrate. Further, when the substrate is shrunk in the latter step, it is necessary to use a shrinkable film. For example, it is possible to use a shrinkable polystyrene film, polyethylene terephthalate film or the like coated with an electroconductive agent as a substrate.

Abrasion in the present invention may be conducted using grinding machine, abrading machine, lapping machine, polishing machine, honing machine, buff abrading machine, CMP device, etc. The sheet may be abraded either in a state of being detached from the substrate or in a state of being fixed to the substrate and including the substrate. Surface roughness of the smooth surface and protruded length of the fiber on the surface wherefrom an insulating and thermally conductive fiber is protruded can be controlled by the particle size of an abrading whetstone or an abrading paper. Although the appropriate particle size differs depending upon the material of the binder resin and of the highly thermally conductive fiber used, smoothness is enhanced when the particle size is increased while, when the particle size is lowered, the fiber is cut and remained whereupon the protruded length becomes long. For example, when polybenzazole fiber is used as an insulating and thermally conductive fiber, a smooth surface having the surface roughness of 4 μm or less is obtained with the particle size of #2000 or more and while, in case the particle size is #400 or less, protruded length becomes 10 μm or more and, when the particle size is further lowered, the protruded length can be made long.

The electrostatic flocking in the present invention is preferred to be conducted by an electrostatic flocking method by which a high flocking density is achieved and, to be more specific, an up method is preferred. In a down method, in addition to the short fiber which is attracted to an opposing electrode along a line of electric force by electrostatic attractive force, the short fiber which is naturally dropped by gravity is also flocked whereby the erect property of the fiber becomes poor. As a result, invasion of other fiber is inhibited by the flocked fiber in an inclined manner whereby it is difficult to flock in high density. On the contrary, in an up method, only the short fiber which is attracted by electrostatic attractive force is flocked whereby the erect property is good and flocking in high density is possible.

In the present invention, it is a point in the manufacture for expressing the high thermal conductivity that an electrostatic flocking is conducted in high flocking density while keeping the erect property of the fiber. It is preferred that an average value of inclination of the insulating and thermally conductive fiber penetrating the sheet in its thickness direction to the sheet surface is 60 to 90°, preferably 65 to 90° and, more preferably, 70 to 90°.

Average value of the ratio of thermal conductivity of the insulating and thermally conductive sheet according to the present invention in the thickness direction to that in the surface direction is preferred to be 2 or more, and more preferred to be 6 or more. As a result of controlling to the above angle, the above ratio of thermal conductivity can be ensured. In order to actualize the high thermal conductivity without deteriorating the flexibility and the light weight property of the binder resin, it is preferred that the thermal anisotropy is high. Thus, it is preferred that orientation in the thickness direction of the insulating and thermally conductive fiber is high and that a high thermal conductivity can be expressed in the thickness direction even with a thermally conductive fiber in a relatively small amount. Further, when the amount of the insulating and thermally conductive fiber is reduced, the interface between the binder resin and the fiber becomes small. As a result, when thermal stress and shock from outside are applied in actual use, detachment at the interface hardly happens whereby a sheet having an excellent long-term durability can be prepared.

In the electrostatical flocking of the present invention, the product (E) of the distance r (cm) between the electrodes and the applied voltage (kV) is preferred to be within a range of the formula 1 and, further, the quotient (a) of the fiber length (mm) by the fineness (D) of the insulating and thermally conductive fiber is preferred to be within a range of the formula 2. When E is less than the range of the formula 1, strength of electric field is insufficient and flocking cannot be conducted in high density. When E is more than 8, dielectric breakdown is generated and electrostatic flocking cannot be conducted normally. When a is 1.5 or less, aspect ratio of the fiber becomes large and it is difficult to keep the erect state by the fiber's own weight. When a is 10.2 or more, aspect ratio becomes small and polarization rate in the fiber axial direction in the fiber becomes small whereby flocking cannot be conducted in high density.

0.25a+3.37≦E≦8 formula 1

(r: distance between the electrodes (cm), V: applied voltage, E=V/r)

2≦a≦10 formula 2

(a: fineness (D)/fiber length (mm))

The above preferred manufacturing condition is shown in FIG. 3. When the electrostatic flocking is conducted within the above range, it is possible to achieve the final penetrating density of the insulating and thermally conductive fiber of 30%.

Flocking density can be controlled by adjusting the E by means of the applied voltage and the distance between the electrodes. When a calibration curve for E and penetrating density of the fiber is previously prepared as shown in FIG. 3 and then the electrostatic flocking is conducted at the E which is suitable for the desired flocking density or, in other words, for the desired penetrating density of the fiber, the flocking density can be controlled.

In the manufacturing steps of the present invention, a step of impregnating a binder resin into an insulating and thermally conductive fiber which is erect on the substrate, and hardening the binder resin can be conducted by any of the following methods: (i) a method for impregnating a binder resin by dissolving or emulsifying in any solvent and then evaporating the solvent by heating to solidify, (ii) a method for impregnating a binder resin in a melted state by heating followed by cooling to harden and (iii) a method for impregnating a binder resin in a state of monomer and hardening the binder resin by heating or by irradiation with energy ray such as ultraviolet, infrared or electronic ray.

### EXAMPLES

Methods for the evaluation of various physical properties in the present invention are as shown below.

Fineness of the insulating and thermally conductive short fiber was calculated according to the following calculating formula from the weight, as measured by an ultramicrobalance (ME5 manufactured by Sartorius Mechatronics Japan), of a test piece prepared by cutting a long fiber bundle in 10 cm length.

Fineness(denier)=Weight(g)×90000

Fiber length of an insulating and thermally conductive short fiber was obtained by calculating the average value of 100 test pieces by observing the short fiber test piece under a microscope.

Fiber diameter of an insulating and thermally conductive short fiber was obtained by calculating the average value of 10 test pieces in terms of the fiber diameter at the middle point in the fiber length direction by observing the short fiber test piece under a microscope.

Thermal conductivity of an insulating and thermally conductive fiber in a fiber axis direction was measured by a stationary heat flow method using a system having a temperature-controlling device equipped with a helium freezer. Length of the sample fiber was made about 25 mm and the fiber bundle was prepared by arranging and bundling about 1,000 single fibers. After that, both ends of the sample fiber were fixed using Stycast GT and set on a sample stand. For the measurement of temperature, an Au-chromel thermocouple was used. As to a heater, a 1 kΩ resistance was used and it was adhered to a fiber bundle end using a varnish. Range for measuring the temperature was made 27° C. For keeping the adiabatic property, the measurement was conducted in vacuo (10⁻³ Pa). Incidentally, the measurement was started after the sample was allowed to stand in vacuo (10⁻³ Pa) for 24 hours to make the sample into a dry state.

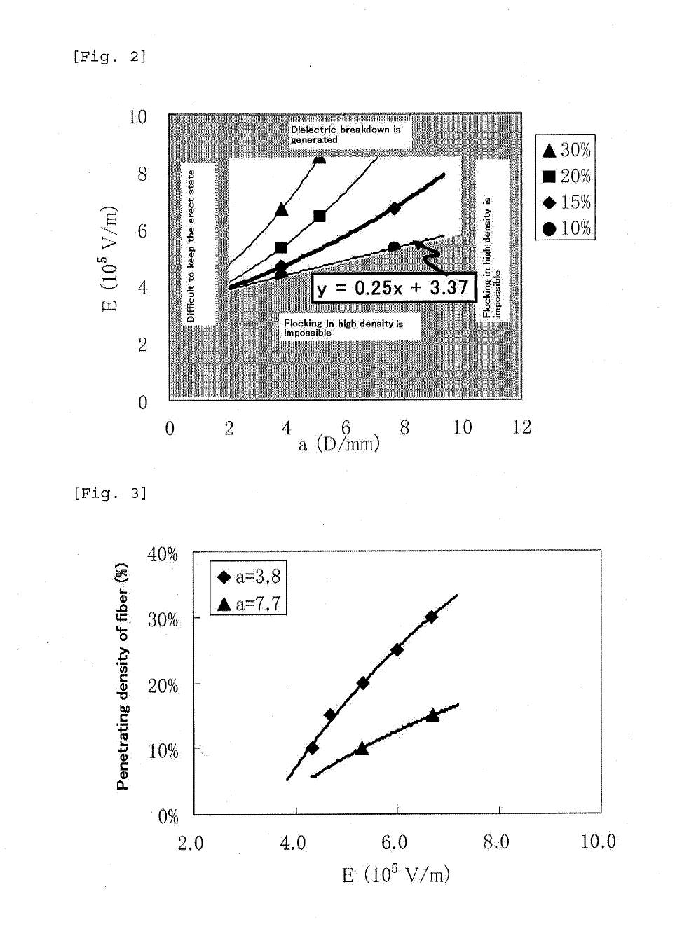

Measurement of thermal conductivity was conducted by flowing a predetermined electric current to a heater so as to make the temperature difference ΔT between the two points (L) 1K. This is shown in FIG. 2. Here, when cross sectional area of the fiber bundle was S, distance between the thermocouples was L, heat quantity given by the heater was Q and the temperature difference between the thermocouples was ΔT, then the thermal conductivity λ to be determined can be calculated by the following calculating formula. Examples measured by using this experimental method will be shown below.

λ(W/mK)=(Q/ΔT)×(L/S)

Volume intrinsic resistivity of the insulating and thermally conductive fiber was measured by the following method.

A long fiber bundle was dried at 105° C. for one hour and then allowed to stand in an atmosphere of 25° C. and 30 RH % for not shorter than 24 hours to adjust the moisture. Positive electrode and earth electrode were made to contact the long fiber bundle with predetermined intervals (5 cm, 10 cm, 15 cm and 20 cm), then voltage of 10 V was applied between both electrodes and the resistance (Ω) was measured by a digital multimeter (R6441 manufactured by Advantest). From this resistance value, volume intrinsic resistance values were determined for each interval length according to the following calculating formula and an average value thereof was adopted as a volume intrinsic resistance value for the sample.

ρ=R×(S/L)

In the formula, ρ is volume resistivity (Ωcm), R is resistance value (Ω) of the test piece, S is cross-sectional area (cm²) and L is length (cm). Incidentally, the cross-sectional area of the test piece was calculated by observing the fiber under a microscope.

Densities of the sheet and the fiber were measured by a dry-type automated densitometer (AccuPyc II 1340 manufactured by Shimadzu).

Volume intrinsic resistance of the sheet was measured under the atmosphere of 25° C. and 60 RH % using a high-resistance resistivity meter (Hiresta-IP manufactured by Mitsubishi Petrochemical) after adjusting the moisture of the sheet for not shorter than 24 hours in an atmosphere of 25° C. and 60 RH %. Applied voltage was switched in the order of 10 V, 100 V, 250 V and 500 V until the voltage by which the measured value was stabilized whereupon the measurement was conducted. Measuring range was automatically set. The value after the measured values were stabilized was adopted as the volume intrinsic resistance.

An average surface roughness of the sheet was measured by a surface roughness shape measuring machine (Softest SV-600 manufactured by Mitsutoyo) wherein the measuring width was set 5 mm and the running speed of contacting needle was set 1.0 mm/s.

Hardness of the sheet was measured in accordance with JIS K 6253.

Thermal conductivity in the sheet thickness direction or in the sheet surface direction was measured by the following calculating formula using the thermal diffusibility in the sheet thickness direction or in the sheet surface direction, respectively as well as the specific heat of the sheet and the density of the sheet. The thermal diffusibility was measured using a thermal physical property measuring device (Thermowave Analyzer TA3 manufactured by Bethel).

λ=α×Cp×ρ formula 4

(λ: thermal conductivity (W/mk), α: thermal diffusibility (m²/s), Cp: specific heat (J/gK), ρ: density (g/m³))

Ratio of thermal conductivity in the thickness direction to that in the surface direction of the sheet was calculated by the following calculating formula using each of average values of thermal conductivities in the thickness direction and the surface direction of the sheet at any five points.

Ratio of thermal conductivity in the thickness direction to that in the surface direction of the sheet=(Average value of thermal conductivity in the thickness direction)÷(Average value of thermal conductivity in the surface direction)

Penetrating density of an insulating and thermally conductive fiber was evaluated by the following methods:
(1) The same coordinate positions of both surfaces of the sheet are adopted as the center of the field and pictures of both surfaces are taken using a lens of 20 magnifications of a reflected light optical microscope;
(2) Numbers of fiber cross sections in the taken picture in each surface are counted;
(3) Content by volume of the fiber in each surface is calculated by the following calculating formula:

Content by volume of the fiber in each surface=[(Numbers of fiber cross-sections in the taken picture)×(Fiber cross-sectional area calculated from fiber diameter)]÷(Area of observed field); and
(4) Among the contents by volume of the fiber on the both surfaces, the smaller value was adopted as the content by volume of the penetrating fiber or, in other words, the penetrating density.

Inclination of the insulating and thermally conductive fiber was evaluated by the following methods;
(1) A sheet is embedded and fixed using epoxy resin followed by abrading so that the cross section of the sheet in the thickness direction is exposed;
(2) Picture of cross section of the sheet in the thickness direction is taken by a 20-magnification lens of a reflected light optical microscope;
(3) Among the fibers in the picture, all fibers which penetrate from the smooth surface to the opposite matrix surface were selected and, between the angles to the smooth surface in the fiber length direction, smaller ones are measured; and
(4) Average value of the measured angles was adopted as the inclination of the fiber.

Heat dissipating property of the sheet was measured by the following methods:
(1) A cylindrical heater (capacity: 35 W) was set in the central area of an aluminum cell in 50 mm length, 2 mm width and 2 mm height and then the temperature of one side of the cell is measured using an infrared thermometer;
(2) Direct current of 0.3 A current value and 100V voltage value is applied to the heater and the temperature after 10 minutes is measured;
(3) After being allowed to cool for 10 minutes, a sample (sheet) is adhered to another side of the cell wherein temperature is not measured; and
(4) Current is applied again at current value of 0.3 A and voltage value of 100 V, the temperature after 10 minutes is measured using an infrared thermometer and the case wherein the temperature is lower than the temperature of the above (2) is marked “O” while the case wherein the temperature is higher than that of the above (2) is marked “x”.

### Example 1

As an insulating and thermally conductive fiber, Zylon HM(R) (manufactured by Toyobo) cut into 400 μm length (heat conductivity in the fiber length direction: 40 W/mK) was used while, as a binder resin liquid, a resin solution prepared by mixing 100 parts by mass of TSE 3431-A (main material of liquid silicone rubber manufactured by Momentive Performance Materials) and 30 parts by mass of TSE 3431-C (curing agent for liquid silicone rubber manufactured by Momentive Performance Materials) was used. As an adhesive, a 10 wt % aqueous solution of polyvinyl alcohol AH-26 (manufactured by Nippon Gosei Kagaku) was used. As a substrate, aluminum foil of 11 μm thickness was used. The binder resin liquid was applied, in 25 μm thickness, onto the substrate on a positive electrode plate. The positive electrode plate was set on the upper part of an earth electrode plate to which Zylon short fiber was set. Distance between the electrodes was made 3 cm. Voltage of 18 kV was applied between the electrodes for 5 minutes to conduct an electrostatic flocking whereupon a flocked sheet was prepared. The resulting flocked sheet was heated at 80° C. for 1 hour to harden the adhesive. After that, the binder resin liquid was applied, in 600 μM thickness, onto the flocked sheet, defoamed in vacuo and solidified by heating at 80° C. for 1 hour. The substrate was detached from the resulting sheet. The side wherefrom the substrate was detached was abraded by the depth of 200 μm using an abrasive paper of #600 particle size and further abraded by the depth of 100 μM using an abrasive paper of #2000 particle size. Still further, the opposite side was abraded by the depth of 100 μm using an abrasive paper of #600 particle size and, furthermore, it was abraded by the depth of 100 μm using an abrasive paper of #2000 particle size whereupon a Zylon-compounded silicone rubber sheet in the final thickness of 100 μm was prepared. Penetrating density of the fiber was 30%, volume intrinsic resistance of the sheet was not less than 10¹⁶ Ω·cm (over the range of the measuring machine) and Shore A hardness was 68. Evaluation in a UL94 flame retardation test was V-0.

### Example 2

The same procedure as in Example 1 was conducted except that, as a binder resin liquid, there was used a liquid prepared by mixing 80.9 parts by weight of UR 3600 (a solution of saturated copolymerized polyester urethane manufactured by Toyobo), 12.0 parts by weight of BX-10SS (a solution of saturated copolymerized polyester urethane manufactured by Toyobo) and 7.1 parts by weight of AH-120 (epoxy resin manufactured by Toyobo) whereupon a Zylon-compounded ester urethane resin sheet was prepared. Incidentally, in this state, the sheet was in a semi-hardened state. Penetrating density of the fiber was 26%. Before the stage of actual use, the sheet in a semi-hardened state is adhered to an exothermic material or a cooling material followed by heating at 140° C. for 4 hours whereby the sheet is completely hardened. Therefore, the volume intrinsic resistance was measured under the completely hardened state. Volume intrinsic resistance of the completely hardened sheet was not less than 10¹⁶ Ω·cm (over the range of the measuring machine).

### Example 3

The same procedure as in Example 1 was conducted except that, as a binder resin liquid, there was used a liquid prepared by mixing 100 parts by weight of UR 3575 (a solution of saturated copolymerized polyester urethane manufactured by Toyobo), and 2.4 parts by weight of HY-30 (epoxy resin manufactured by Toyobo) whereupon a Zylon-compounded ester urethane resin sheet was prepared. Incidentally, in this state, the sheet was in a semi-hardened state. Penetrating density of the fiber was 26%, and volume intrinsic resistance of the sheet was not less than 10¹⁶ Ω·cm (over the range of the measuring machine).

### Example 4

The same procedure as in Example 1 was conducted except that Yodosol AA76 (manufactured by Henkel Japan) which is an aqueous dispersion of acrylic resin was used as a binder resin liquid and the heating/hardening was conducted at 80° C. for 1 hour whereupon a Zylon-compounded acrylic resin sheet was prepared. Penetrating density of the fiber was 9%, and volume intrinsic resistance of the sheet was 3.65×10¹¹ Ω·cm.

### Example 5

The same procedure as in Example 1 was conducted except that the side which was opposite to the side wherefrom a substrate was detached was abraded using an abrasive paper of #100 particle size to the depth of 300 μm whereupon a Zylon-compounded silicone rubber was prepared. Penetrating density of the fiber was 29%, and volume intrinsic resistance of the sheet was not less than 10¹⁶ Ω·cm (over the range of the measuring machine) and Shore A hardness was 68. Evaluation in a UL94 flame retardation test was V-0. Evaluation in the heat dissipating property measurement was O.

### Example 6

The same procedure as in Example 2 was conducted except that the applied thickness of an adhesive was changed to 50 μm whereupon a Zylon-compounded ester urethane resin sheet was prepared. Penetrating density of the fiber was 10%, and volume intrinsic resistance of the sheet was not less than 10¹⁶ Ω·cm (over the range of the measuring machine).

### Comparative Example 1

The same procedure as in Example 2 was conducted except that a polyethylene terephthalate film of 50 μm thickness was used as a substrate and that the applied thickness of an adhesive was changed to 120 μm whereupon a Zylon-compounded ester urethane resin sheet was prepared. Penetrating density of the fiber was 5%, and volume intrinsic resistance of the sheet was not less than 10¹⁶ Ω·cm (over the range of the measuring machine) Evaluation in the heat dissipating property measurement was x.

### Comparative Example 2

The same procedure as in Example 2 was conducted except that a polyethylene terephthalate film of 50 μm thickness was used as a substrate and that the applied thickness of an adhesive was changed to 400 μm whereupon a Zylon-compounded ester urethane resin sheet was prepared. Penetrating density of the fiber was 3%, and volume intrinsic resistance of the sheet was not less than 10¹⁶ Ω·cm (over the range of the measuring machine) Evaluation in the heat dissipating property measurement was x.

### Comparative Example 3

A flocked sheet prepared by the same procedure as in Example 1 was heated at 80° C. for 1 hour to harden the adhesive. After that, the same binder resin liquid as in Example 1 was applied, in 600 μm thickness, onto the flocked sheet, defoamed in vacuo and solidified by heating at 80° C. for 1 hour. The substrate was detached from the resulting sheet. The side wherefrom the substrate was detached was abraded by the depth of 200 μm using an abrasive paper of #600 particle size and further abraded by the depth of 100 μm using an abrasive paper of #100 particle size. Still further, the opposite side was abraded by the depth of 100 μm using an abrasive paper of #600 particle size and, furthermore, it was abraded by the depth of 100 μm using an abrasive paper of #100 particle size whereupon a Zylon-compounded silicone rubber sheet in the final thickness of 100 μm was prepared. Penetrating density of the fiber was 30%, and volume intrinsic resistance of the sheet was not less than 10¹⁶ Ω·cm (over the range of the measuring machine) and Shore A hardness was 68. Evaluation in a UL94 flame retardation test was V-0. Average value of protruded length of the fiber was 80 μm on both sides of the sheet.

### Comparative Example 4

The same procedure as in Example 2 was conducted except that voltage applied to between electrodes was changed to 10 kV whereupon a Zylon-compounded ester urethane resin sheet was prepared. Penetrating density of the fiber was 5%, and volume intrinsic resistance of the sheet was not less than 10¹⁶ Ω·cm (over the range of the measuring machine) Evaluation in the heat dissipating property measurement was x.

### Comparative Example 5

The same binder resin liquid as in Example 1 was mixed with Zylon HM (R) cut in a 400 μm length so as to make the content by volume 20% followed by stirring for 5 minutes. The resulting Zylon-compounded resin liquid was applied, to an extent of 100 μm thickness, on a polyethylene terephthalate film of 50 μm thickness and set on the upper area of an earth electrode plate and then voltage of 18 kV was applied between the electrodes for 5 minutes followed by heating/solidifying at 80° C. for 1 hour. Penetrating density of the fiber of the resulting Zylon-compounded silicone rubber sheet was 2%, and volume intrinsic resistance of the sheet was not less than 10¹⁶ Ω·cm (over the range of the measuring machine) and Shore A hardness was 68. Evaluation in a UL94 flame retardation test was V-0.

TABLE 1

| | | Example 1 | Example 2 | Example 3 | Example 4 | Example 5 | Example 6 |
|---|---|---|---|---|---|---|---|
| Substrate | | Al | Al | Al | Al | Al | Al |
| Binder | | Si rubber | UR3600 | UR3537 | acrylic | Si rubber | UR3600 |
| Adhesive | Material | PVA solution | PVA solution | PVA solution | PVA solution | PVA solution | PVA solution |
| | Thickness of | 25 | 25 | 25 | 25 | 25 | 50 |
| | adhesive [μm] | | | | | | |
| Voltage [kV] | | 18 | 18 | 18 | 18 | 18 | 18 |
| Distance between electrodes | | 3 | 3 | 3 | 3 | 3 | 3 |
| [cm] | | | | | | | |
| Particle size of abrasive paper | | #600→#2000 | #600→#2000 | #600→#2000 | #600→#2000 | #600→#2000 | #600→#2000 |
| Penetrating density [%] | | 30 | 26 | 26 | 22 | 29 | 20 |
| Angle [°] | | 71 | 74 | 70 | 70 | 74 | 63 |
| Thermal conductivity in the | | 11.9 | 9.4 | 9.2 | 9.4 | 12.0 | 5.1 |
| thickness direction [W/mK] | | | | | | | |
| Thermal conductivity in the | | 1.1 | 0.9 | 1.2 | 1.0 | 0.9 | 2.1 |
| surface direction [W/mK] | | | | | | | |
| Thickness/surface thermal | | 10.8 | 10.4 | 7.7 | 9.4 | 13.3 | 2.4 |
| conductivity ratio | | | | | | | |
| Surface | (Surface A) | 4 | 2 | 2 | 2 | 3 | 4 |
| roughness | (Surface B) | 3 | 2 | 2 | 2 | 40 | 4 |
| [μm] | | | | | | | |
| Protruded | (Surface A) | ~2 | ~1 | ~1 | ~1 | ~1 | ~4 |
| length [μm] | (Surface B) | ~2 | ~1 | ~1 | ~1 | 60~100 | ~4 |

| | | Comparative | Comparative | Comparative | Comparative | Comparative |
|---|---|---|---|---|---|---|
| | | Example 1 | Example 2 | Example 3 | Example 4 | Example 5 |
| Substrate | | PET | PET | Al | Al | PET |
| Binder | | UR3600 | UR3600 | Si rubber | UR3600 | Si rubber |
| Adhesive | Material | Si rubber resin | Si rubber resin | PVA aqueous | PVA aqueous | — |
| | | liquid | liquid | solution | solution | |
| | Thickness of | 120 | 400 | 25 | 25 | — |
| | adhesive [μm] | | | | | |
| Voltage [kV] | | 18 | 18 | 18 | 10 | 18 |
| Distance between electrodes | | 3 | 3 | 3 | 3 | 3 |
| [cm] | | | | | | |
| Particle size of abrasive paper | | #600→#2000 | #600→#2000 | #600→#100 | #600→#2000 | — |
| Penetrating density [%] | | 5 | 3 | 28 | 5 | 2 |
| Angle [°] | | 41 | 29 | 71 | 35 | 14 |
| Thermal conductivity in the | | 2.1 | 1.2 | 11.2 | 2.4 | 1.0 |
| thickness direction [W/mK] | | | | | | |
| Thermal conductivity in the | | 2.2 | 1.2 | 1.0 | 1.9 | 2.0 |
| surface direction [W/mK] | | | | | | |
| Thickness/surface thermal | | 1.0 | 1.0 | 11.2 | 1.3 | 0.5 |
| conductivity ratio | | | | | | |
| Surface | (Surface A) | 4 | 4 | 74 | 4 | 4 |
| roughness | (Surface B) | 3 | 3 | 63 | 3 | 3 |
| [μm] | | | | | | |
| Protruded | (Surface A) | ~4 | ~4 | 50~100 | ~4 | ~4 |
| length [μm] | (Surface B) | ~4 | ~4 | 40~100 | ~4 | ~4 |

### INDUSTRIAL APPLICABILITY

In accordance with the insulating and thermally conductive sheet of the present invention, effective thermal conductance and heat dissipation from an exothermic material such as electronic substrate, semiconductor chip, light source, etc. are now possible while ensuring electric insulating property. As a result, deterioration of electronic instrument, light source, etc. by heat can be reduced whereby the life can be extended. Accordingly, the present invention is expected to greatly contribute in the industrial world.

### EXPLANATION OF REFERENCE NUMBER

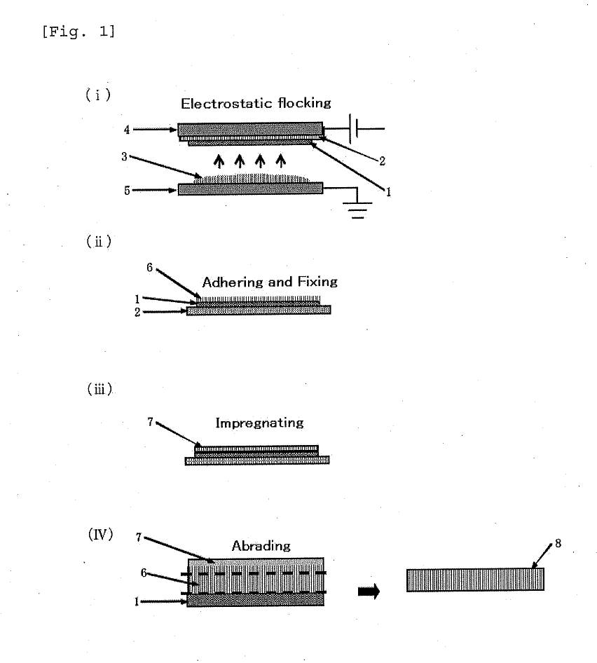

(FIG. 1)
1: adhesive
2: substrate film
3: insulating and thermally conductive short fiber
4: positive electrode
5: earth electrode
6: insulating and thermally conductive short fiber in erect state
7: binder resin
8: insulating and thermally conductive sheet

1. An insulating and thermally conductive sheet, characterized in that, the sheet contains an insulating and thermally conductive fiber which penetrates the sheet in its thickness direction and a binder resin, that the surface roughness on at least one side of the sheet is 15 μm or less, and that the penetrating density of the insulating and thermally conductive fiber is 6% or more.

2. The insulating and thermally conductive sheet according to claim 1, wherein an average value of the ratio of thermal conductivity of the insulating and thermally conductive sheet in the thickness direction to that in the surface direction is 2 to 12.

3. The insulating and thermally conductive sheet according to claim 1, wherein an average value of inclination of the insulating and thermally conductive fiber to the sheet surface is 60 to 90°.

4. The insulating and thermally conductive sheet according to claim 1, wherein the insulating and thermally conductive fiber is protruded in the length of 50 to 1,000 μm on a surface (surface B) opposite to the smooth surface (surface A) having the surface roughness of 15 μm or less.

5. The insulating and thermally conductive sheet according to claim 1, wherein the durometer hardness is 80 or less in terms of Shore A hardness and 5 or more in terms of Shore E hardness.

6. The insulating and thermally conductive sheet according to claim 1, wherein the volume intrinsic resistance is 10¹² Ω·cm or more.

7. The insulating and thermally conductive sheet according to claim 1, wherein the evaluation in a UL 94 flame resistance test is V-0.

8. The insulating and thermally conductive sheet according to claim 1, wherein the insulating and thermally conductive fiber is any of boron nitride fiber, high-strength polyethylene fiber and polybenzazole fiber.

9. The insulating and thermally conductive sheet according to claim 1, wherein the binder resin is any of silicone resin, acrylic resin, urethane resin, EPDM resin and polycarbonate resin.

10. The insulating and thermally conductive sheet according to claim 1, wherein the penetrating density of the insulating and thermally conductive fiber is 6 to 50%.

11. A method for manufacturing an insulating and thermally conductive sheet, characterized in that, the method comprises:
a step of erecting an insulating and thermally conductive short fiber by means of electrostatic flocking, onto a substrate to which an adhesive is applied;
a step of adhering and fixing the erected insulating and thermally conductive short fiber by heating and, optionally shrinking the substrate together with the adhesion/fixing or after the adhesion/fixing;
a step of impregnating a binder resin into the insulating and thermally conductive short fiber which is erected on the substrate, and hardening the binder resin; and
a step of abrading both surfaces under the state of being detached from the substrate or of being fixed to the substrate.
